(19) United States
(12) Patent Application Publication
(10) Pub. No.: US 2006/0039189 A1
(43) Pub. Date: Feb. 23, 2006

(54) Magnetic random access memory with tape read line, fabricating method and circuit thereof

(75) Inventors: Young-Shying Chen, Hsinchu (TW); Ming-Jer Kao, Hsinchu (TW); Lien-Chang Wang, Hsinchu (TW); Chien-Chung Hung, Hsinchu (TW); Chi-Ming Chen, Hsinchu (TW)

Correspondence Address: BIRCH STEWART KOLASCH & BIRCH, PO BOX 747, FALLS CHURCH, VA, 22040-0747, US

(73) Assignee: Industrial Technology Research Institute

(21) Appl. No.: 11/033,169

(22) Filed: Jan. 12, 2005

(30) Foreign Application Priority Data
Aug. 18, 2004 (TW) 93124835

(51) Int. Cl. G11C 11/00; G11C 5/06

(52) U.S. Cl. 365/158; 365/63

(57) ABSTRACT

A magnetic random access memory with tape read line, fabricating method and circuit thereof is provided. The memory is composed of a top write line, a bottom write line which is vertical to the top write line, a MTJ formed on the bottom write line, a spacer formed around the MTJ, and a tape read line formed on the MTJ. The fabricating steps involves forming a bottom write line, forming a MTJ on the bottom write, and forming a tape read line on the MTJ sequentially. In the circuit, the tape read line is either parallel to or vertical to the top write line.

This Non-provisional application claims priority under 35 U.S.C. § 119(a) on Patent Application No(s). 093124835 filed in Taiwan, R.O.C on Aug. 18, 2004, the entire contents of which are hereby incorporated by reference.

### BACKGROUND OF THE INVENTION

1. Field of Invention

The invention relates to a magnetic random access memory (MRAM) and, in particular, to a MRAM with a tape read line.

2. Related Art

The MRAM is a type of non-volatile memory. It uses resistance properties to store information. It has non-volatility, high density, high read/write speed, and anti-radiation. When writing in data, a common method is to use two wires, the bit line and the write word line, to produce inductance magnetic fields. The magnetization direction in the memory layer of the cell at the intersection is changed to modify its resistance. When reading data from the MRAM, a current needs to be supplied to the selected magnetic memory cell, using its resistance to determine the value of the data.

The magnetic memory cell between the bit line and the write word line is a stack structure of multiple magnetic metal materials. It is formed by piling up a soft magnetic layer, a tunnel barrier layer, a hard magnetic layer, and a nonmagnetic conductor layer. The magnetization directions of two layers of magnetic materials determine whether a bit is “0” or “1.”

The MRAM disclosed in the U.S. Pat. Nos. 6,714,442 and 6,714,440 has the read line and the top write word line prepared separately. However, it still requires a photolithography process for the lower electrode. The MRAM disclosed in the U.S. Pat. Nos. 6,711,053 and 6,606,263 has the magnetic tunnel junction (MTJ) fabricated on the bottom write word line. U.S. Pat. No. 6,653,703 prepares the bottom write word line and the lower electrode of the MTJ together. The oxide layer is polished by chemical-mechanical machining until the top of the MTJ is exposed before making the upper electrode.

As the memory device becomes smaller, many technical problems start to show up. For example, the MRAM faces the problem that the write-in current needed to change data approaches the current density limit that metal wire can convey, causing the electron migration problem. Moreover, the MTJ structure traditionally used to connect the lower electrode and the read word line faces the demand for a small area of the lower electrode and has difficulties in photolithography and etching processes. Thus, it becomes very hard to further minimize the memory device size.

In addition, the via etching process connecting the bit line and the magnetic memory cell is affected by the homogeneity of the polished oxide layer. It is likely to result in damages to the magnetic memory cell because of unfinished vias from insufficient etching or over-etching.

Another problem is that the lower electrode manufacturing process has such restrictions as the minimal area of exposure alignment and the narrowest span. Too large area and too narrow span will both challenge the error range allowed by the exposure aligning machine. Once the exposure alignment has a deviation, the pattern defined by the previous MTJ etching process will be damaged during the lower electrode etching. This may seriously damage the device. Alternatively, the lower electrode may be connected to the contact of the transistor, resulting in the open circuit problem.

### SUMMARY OF THE INVENTION

In view of the foregoing, an objective of the invention is to provide a MRAM with a tape read line to solve the problems existing in the prior art.

According to the objective of the invention, the disclosed MRAM has the advantages of reducing the required write-in current and thus the power consumption during the write word cycle.

According to the objective of the invention, the disclosed MRAM has the advantage of minimizing the memory device size by removing the lower electrode minimal area requirement.

According to the objective of the invention, the disclosed MRAM has the advantage of enhancing the stability of manufacturing process.

To achieve the above-mentioned objective and advantages, the disclosed MRAM with a tape read line contains a write word line, including an top write word line and a bottom write word line, to provide the write-in current of the MRAM; a magnetic tunnel junction (MTJ), formed on and in contact with the bottom write word line; a sidewall, formed around the MTJ; and a tape read line, connected between the MTJ and an connect pad to provide the read-out current of the MRAM.

To achieve the above objective and advantages, the disclosed MRAM circuit has several top write word lines; several bottom write word lines, each of which is perpendicular to each of the top write word lines; several read word lines, each of which is perpendicular to each of the top write word lines and each of the bottom write word lines; several MRAM's, provided at the intersections of the top write word lines and the bottom write word lines; and several transistors, provided at the intersections of the top write word lines and the bottom write word lines and connected to the MRAM so that each transistor has an associated MRAM.

The tape read line design of the invention can be used to fabricate MRAM with a high-density three-dimensional structure.

To achieve the above objective and advantages, an embodiment of the invention includes: several top write word lines and several bottom write word lines to provide write-in current channels for the MRAM; several MTJ's, each of which is formed on the corresponding write word line by stacking, the top write word line of the MTJ in the lower level are shared with the bottom write word line of the MRAM in the upper level; several a tape read line formed on the MTJ and several lower electrodes formed under and in contact with the MTJ to provide parallel or serial current channels among the stacked MRAM's; several first plugs connecting the a tape read line; several second plugs connecting the lower electrodes; and several third plugs connecting the a tape read line and the lower electrodes.

To achieve the above objective and advantages, an embodiment of the fabrication method of the disclosed MRAM with a tape read line includes the following steps. First, make a MRAM, including forming a bottom write word line, forming a MTJ on the bottom write word line, and forming a tape read line and an connect pad on the MTJ. Afterwards, form a top write word line on the MRAM. Then form a first plug connected with the tape read line. Form a second plug connected with the connect pad. Finally, form another MRAM on the top write word line.

To achieve the above objective and advantages, another embodiment of the fabrication method of the disclosed MRAM with a tape read line includes the following steps. First, make a MRAM, including forming a bottom write word line, forming a MTJ on the bottom write word line, and forming a tape read line and an connect pad on the MTJ. Afterwards, form a top write word line on the MRAM. Then form a plug connected with the tape read line and the connect pad. Finally, form another MRAM on the top write word line.

According to the objective, advantages and contents of the invention, the disclosed MRAM with a tape read line achieves the following effects.

The lower electrode of the magnetic memory cell is directly attached on the bottom write word line. The current for reading data flows in through the bottom write word line.

The sidewall spacer processed adopted by the invention solves the problem of short-circuiting due to back coating of the etched metal.

The invention uses the hard mask with a defined pattern on the top layer of the MTJ as the mask for etching the lower electrode, providing a self-alignment mechanism.

The contact after the lower electrode is completed is opened on a deposited dielectric layer whose thickness is under control. There is no thickness homogeneity problem that usually occurs after chemical-mechanical polishing (CMP).

The read word line only allows a very small read-out current to flow through. There is no limit in the carrying current density. Therefore, the wires can be prepared using a metal that is easy to be etched.

In the invention, the metal wire carries a smaller current to produce a larger magnetic field concentrated on the memory cells. This also overcomes the limitation in the lower electrode production.

It is to be understood that both the foregoing general description and the following detailed description are exemplary and explanatory, and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 is a structural diagram of the disclosed MRAM with a tape read line;

FIGS. 2A to 2G show the steps of making the disclosed MRAM with a tape read line;

FIGS. 3A to 3L show the steps of making the disclosed MRAM with a tape read line and a high-density three-dimensional structure;

FIGS. 4A and 4B show the steps of making the disclosed MRAM with a tape read line and a parallel structure;

FIG. 5 shows the disclosed MRAM with a tape read line and a serial structure;

FIG. 6 shows a layout of the disclosed MRAM with a tape read line;

FIG. 7 shows a circuit structure of the disclosed MRAM with a tape read line; and

FIG. 8 shows another circuit structure of the disclosed MRAM with a tape read line.

### DETAILED DESCRIPTION OF THE INVENTION

The present invention will be apparent from the following detailed description, which proceeds with reference to the accompanying drawings, wherein the same references relate to the same elements.

In the following description, for purposes of explanation, numerous specific details are set forth in order to provide a thorough understanding of the invention. It will be apparent, however, to one skilled in the art that the invention can be practiced without these specific details. In other instances, structures and devices are shown in block diagram form in order to avoid obscuring the invention.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

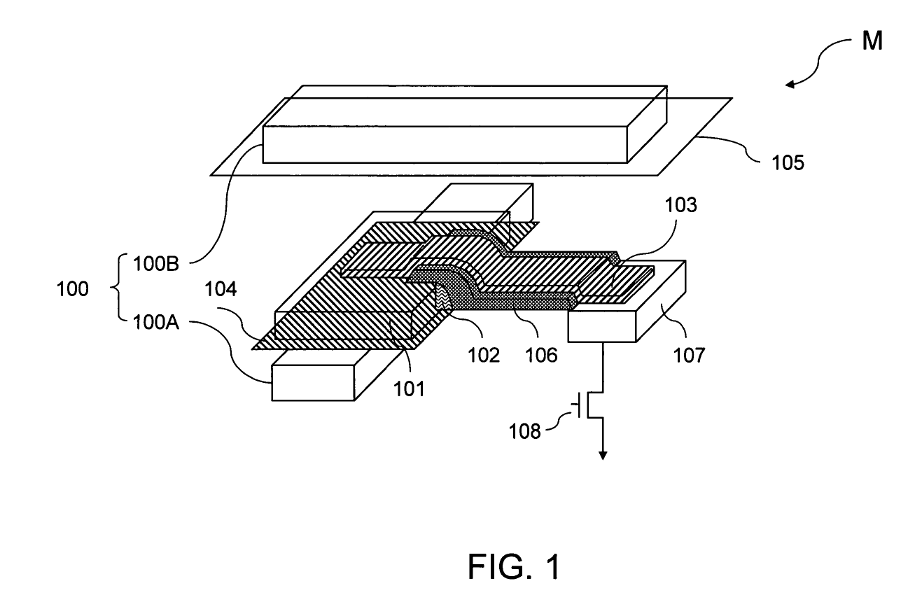

As shown in FIG. 1, the disclosed MRAM with a tape read line consists of a write word line 100, a MTJ 101, a sidewall 102 formed around the MTJ 101, and a tape read line 103. The write word line 100 comprises an upper wire word line 100A and a bottom write word line 100B to provide write-in current channels for the MRAM. The directions of the upper wire word line 100A and the bottom write word line 100B are perpendicular to each other. The MTJ 101 is formed in contact on the bottom write word line 100B, functioning as the memory kernel of the MRAM. Its memory state is changed by changing its magnetization direction. The MTJ 101, for example, can be formed by stacking a soft magnetic layer, a tunnel barrier layer, a hard magnetic layer, and a nonmagnetic conductor.

The sidewall 102 is formed around the MTJ 101 to provide it. The sidewall 102 can be made by the deposition and etching of a dielectric layer. The tape read line 103 provides a read-out current channel for the MRAM M, in contact with the MTJ 101.

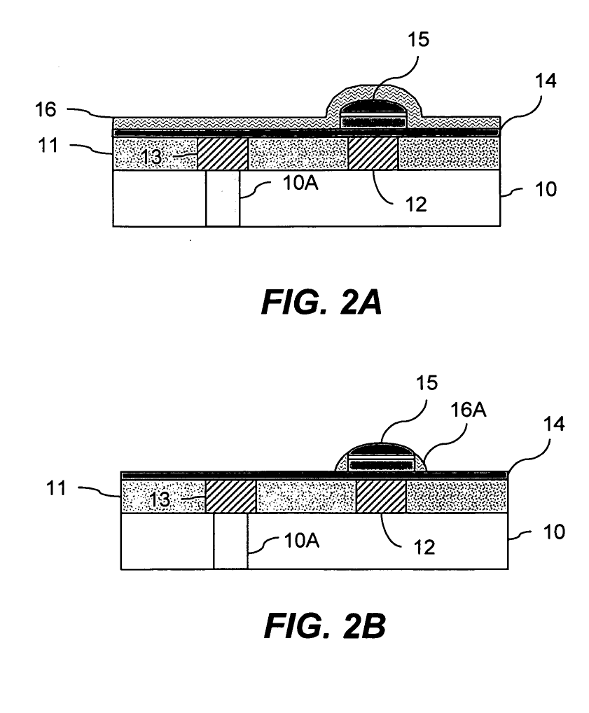

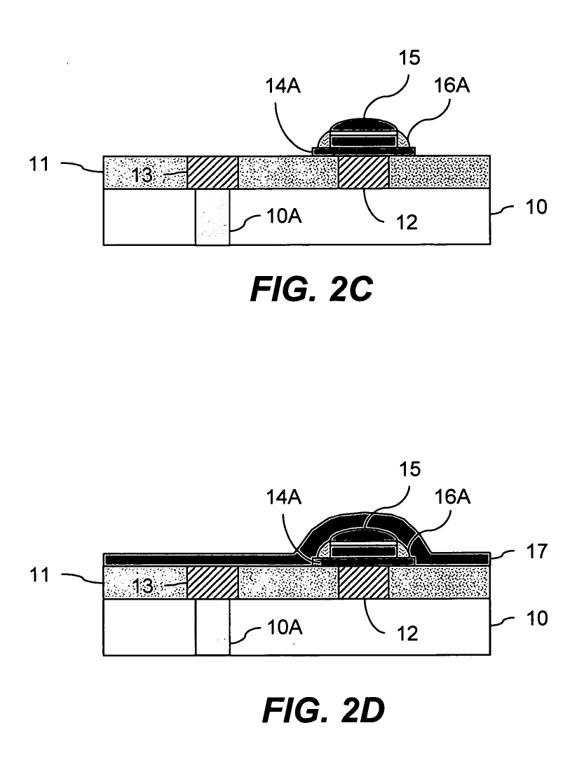

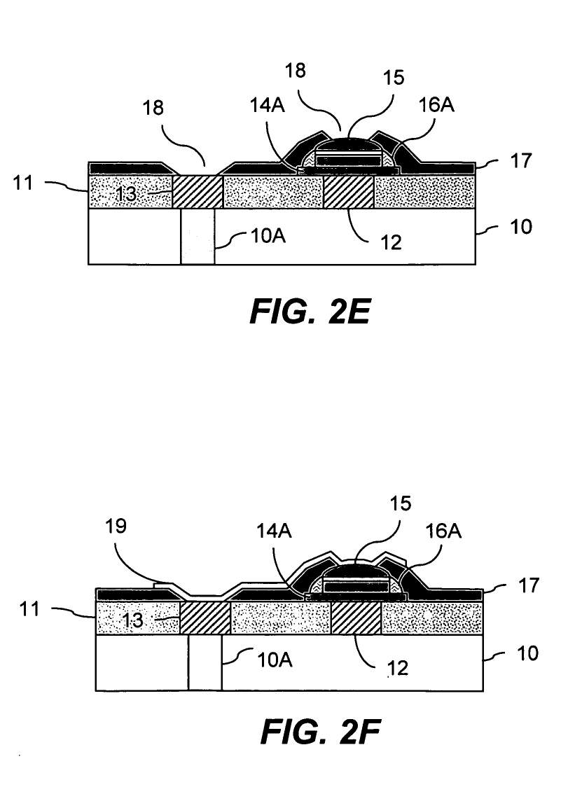

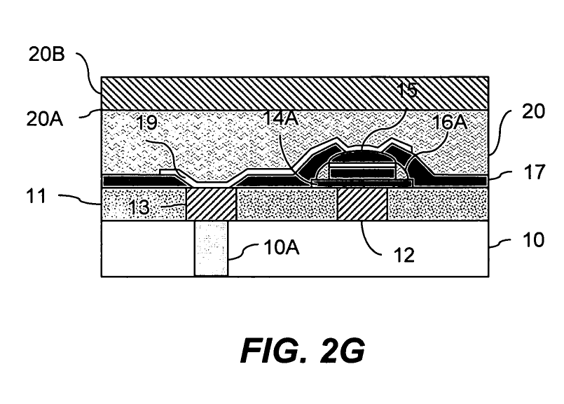

The lower electrode 104 under the MTJ 101 is directly attached on the bottom write word line 100A. A dielectric layer 106 is formed between the tape read line 103 and the sidewall 102. During the fabrication, a contact is formed on a dielectric or insulating layer, so that the tape read line 103 is contact with the MTJ 101 via the contact. The detail will be described with reference to FIG. 2.

The top 105 of the dielectric layer at the bottom of the top write word line 100B is the interface of the dielectric layer 106 after CMP. The tape read line 103 connects the MTJ 101 to the connect pad 107 and to a data read-out transistor 108. A contact is formed using a dielectric or insulating layer, so that the tape read line 103 is in contact with the connect pad 107 via the contact. The detail will be described with reference to FIG. 2.

From the structure shown in FIG. 1, one sees that the MTJ 101 is connected with the data read-out transistor via the tape read line 103. Under this structure, the MTJ 101 has a smaller bit size and solves the difficulty in the exposure alignment process of the lower electrode 104. The distance between the dielectric layer top 105 and the MTJ 101 can be controlled using the CMP, so that the distance between the top write word line 100B of the dielectric layer top 105 and the MTJ 101 is closer. Therefore, the write-in current of the top write word line can be reduced.

The manufacturing process of the disclosed MRAM with a tape read line is shown in FIGS. 2A to 2G.

A first insulating layer 11 is formed on a semiconductor substrate 10 that has gone through the beginning CMOS process. Afterwards, a bottom write word line 12 and a connect pad 13 are formed in the first dielectric layer 11. A plug 10A is formed in the semiconductor substrate 10 to connect to a transistor (not shown) in the semiconductor substrate 10. It is used to read out the current of the MRAM.

A first metal layer 14 is deposited on the first insulating layer 11 as the lower electrode. A MTJ 15 is then formed on the first metal layer 14. A second insulating layer 16 is deposited to cover the MTJ 15 as the sidewall spacer to protect the MTJ 15. The MTJ, for example, is formed by stacking a soft magnetic layer, a tunnel barrier layer, a hard magnetic layer, and a nonmagnetic conductor.

Afterwards, the second insulating layer 16 is etched to form the sidewall 16A around the MTJ 15, as shown in FIG. 2B. The first metal layer 14 is then etched to form the lower electrode 14A, as shown in FIG. 2C. We see from there that the MTJ 15 is in direct contact with the bottom write word line 12. More precisely, the MTJ 15 is in direct contact with the bottom write word line 12 via the lower electrode 14A. The sidewall 16A around the MTJ 15 is used to avoid short-circuiting because of the metal back coating onto the sidewall of the MTJ 15 when etching the lower electrode 14A. The hard mask with defined pattern left on the MTJ functions as the mask for etching the lower electrode 14A, providing a self alignment mechanism. Since the MTJ 15 is in direct contact with the bottom write word line 12 via the lower electrode 14A, the write-in current of the bottom write word line can be reduced. Besides, the bottom write word line generates heat as the write-in current flows through. This heats up the MTJ 15 to reduce its coercive field, thereby reducing the write-in current of the top write word line.

After the lower electrode 14A is formed, a third insulating layer 17 is deposited as shown in FIG. 2D. A contact 18 is defined at the MTJ 15 and the connect pad 13 using photo resist and etching, as shown in FIG. 2E. Afterwards, a second metal layer is deposited on the third insulating layer 17 and the contact 18. It is then etched to form a tape read line 19 (the tape read line 103 in FIG. 1). As shown in FIG. 2F, the MTJ 15 is connected to the connect pad 13 using the contact 18 and the tape read line 19. It is further connected to a data reading transistor (not shown) via the plug 10A. Using the tape read line 19 formed from the contact 18 and the second metal layer, the MTJ 15 is connected to the data reading transistor avoiding the lower electrode 14A. The MTJ 15 in this structure thus has a smaller bit size, solving the difficulty in lower electrode exposure alignment.

Finally, a fourth insulating layer 20 is deposited, followed by CMP to form a planarized interface 20A (the dielectric layer top 105 in FIG. 1). The insulating layer 20 is then formed with a top write word line 20B, as shown in FIG. 2G. The distance between this planarized interface 20A and the MTJ 15 can be controlled by the CMP process, so that the write word line 20B on the interface 105 can be closer to the MTJ 15. This further reduces the write-in current on the top write word line.

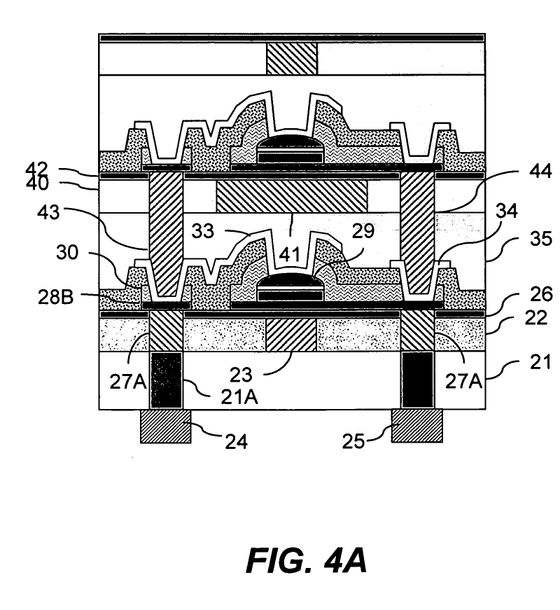

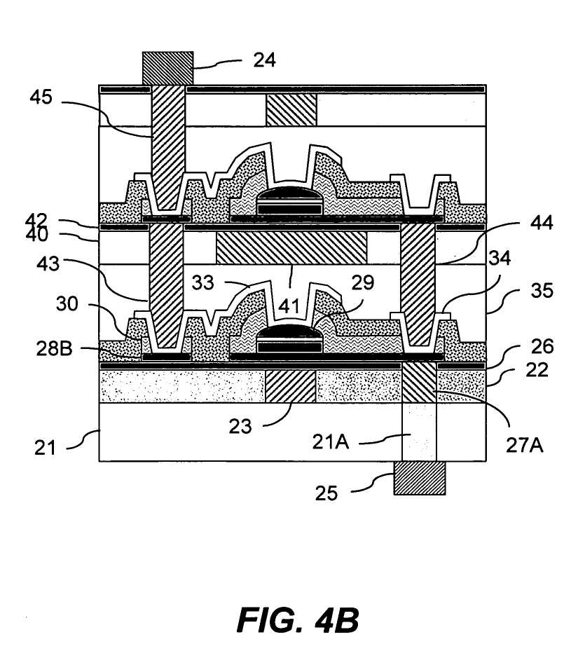

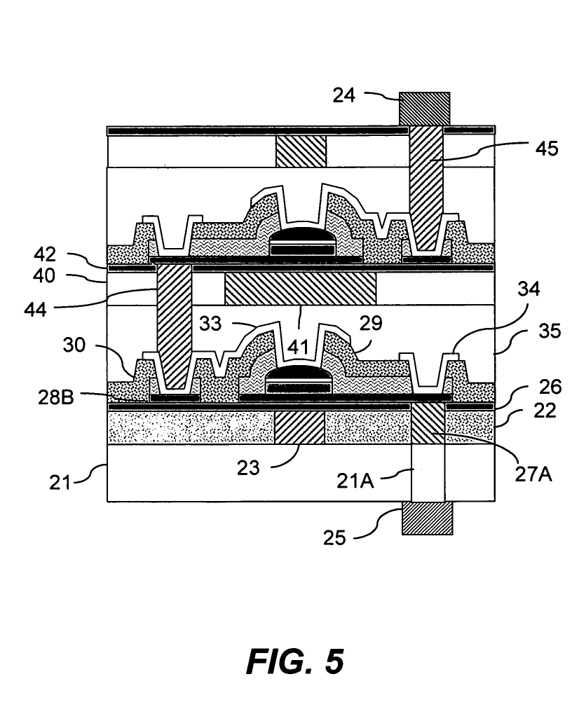

According to the disclosed tape read line design, along with the toggle-mode write-in method, we are able to produce memory with a high-density three-dimensional structure. FIGS. 4 and 5 demonstrate respectively parallel and serial three-dimensional structures of the MRAM with a tape read line.

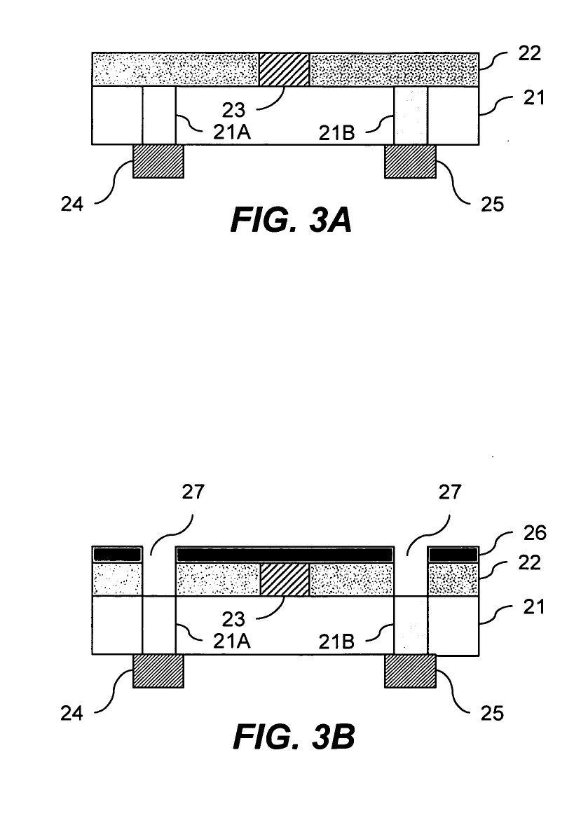

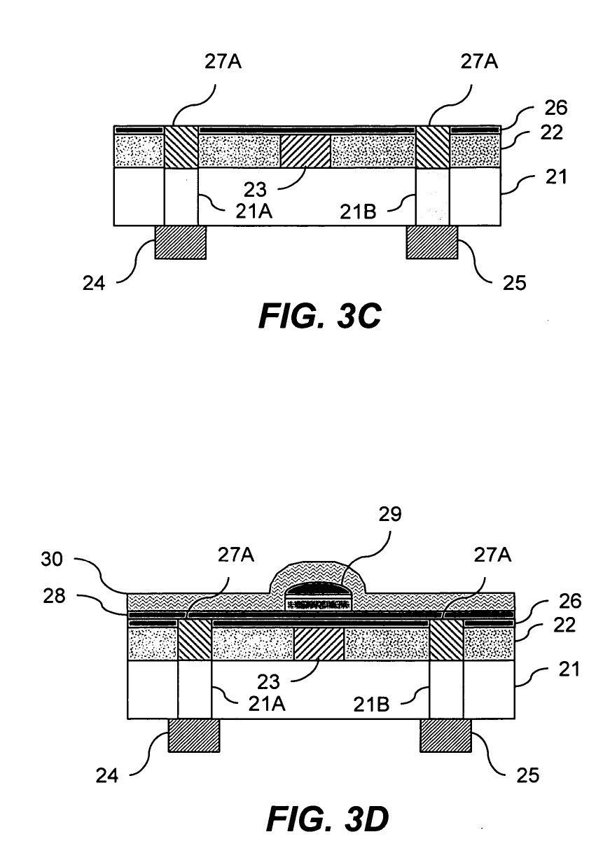

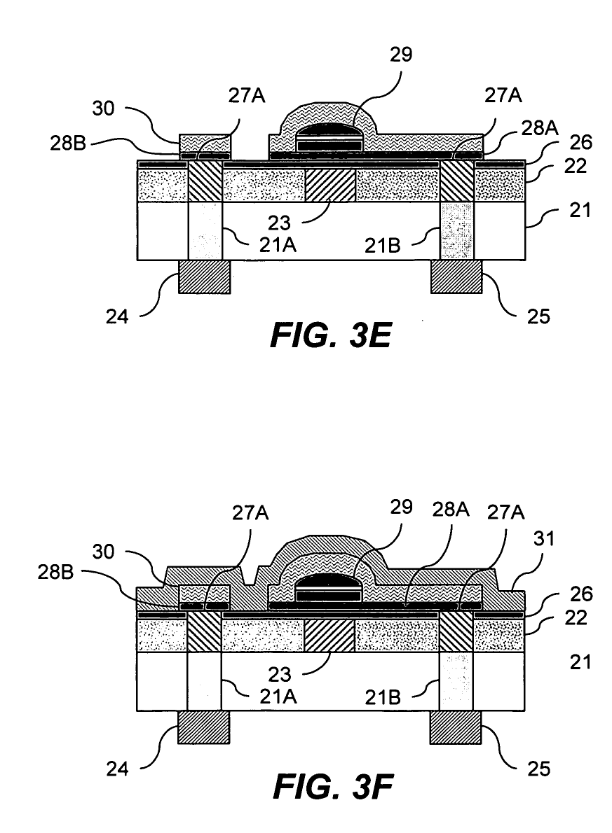

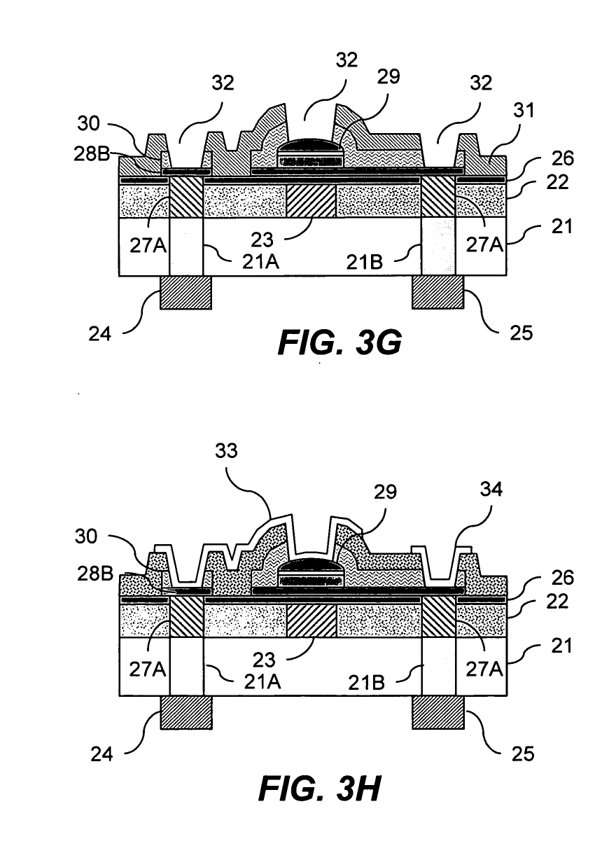

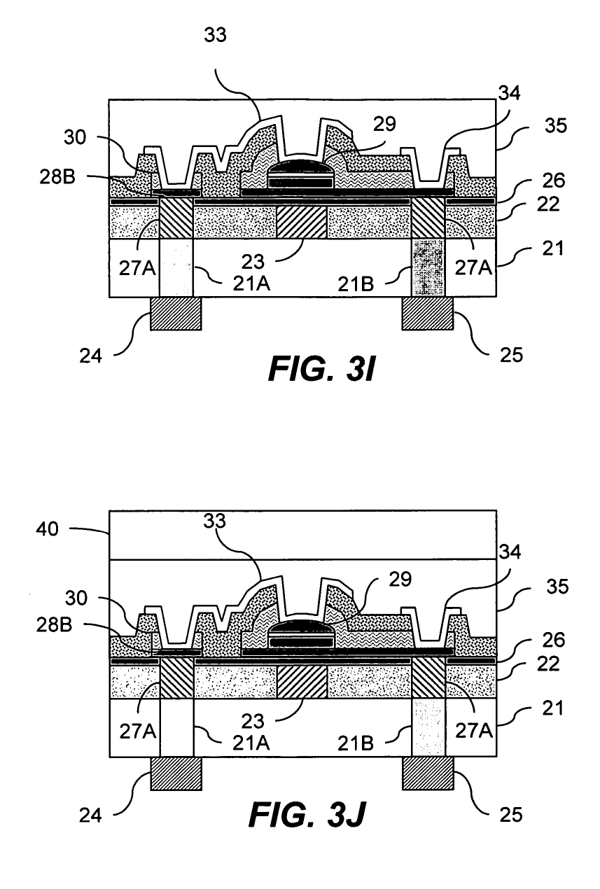

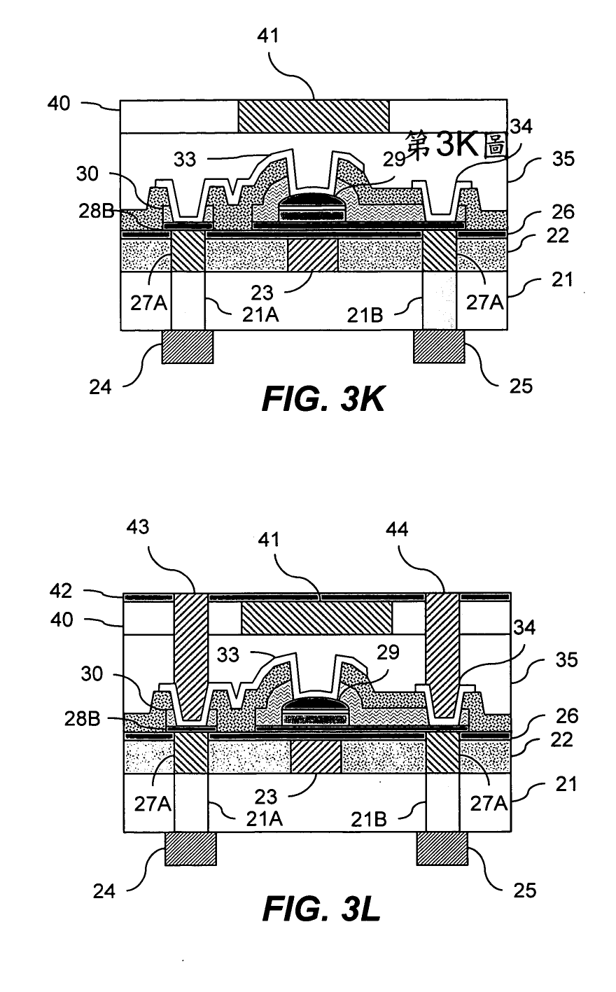

The production process of the parallel three-dimensional structure of the MTJ is shown in FIGS. 3A to 3L. First, a first insulating layer 22 is formed on a semiconductor substrate 21 that has gone through the beginning CMOS process. A bottom write word line 23 is then formed in the first insulating layer 22. The semiconductor substrate 21 has plugs 21A, 21B connected to the read word line 24 and the connect pad 25, respectively. The connect pad 25 is connected to a transistor (not shown), as shown in FIG. 3A.

Afterwards, a second insulating layer 26 is deposited on the first insulating layer 22. Vias 27 are formed at the plugs 21A, 21B by photolithography and etching processes. The vias are then filled with a metal to form the plug 27A, as shown in FIGS. 3B and 3C.

Afterwards, a first metal layer 28 is deposited. A MTJ 29 is fabricated on the metal layer 28 at the bottom write word line 23, covering the second insulating layer 30, as shown in FIG. 3D. The lower electrode 28A and the connect pad 28B are formed by employing photolithography and etching processes. A third insulating layer 31 is deposited on the second insulating layer 30, as shown in FIGS. 3E and 3F.

A contact 32 is then defined at the MTJ 29 and the plug 27A using photo resist and etching. A second metal layer is then deposited. A tape wire 33 and a connect pad 34 are formed using photo resist and etching, connecting the MTJ 29 to the read word line and the data-reading transistor. Finally, an insulating layer 35 is deposited, as shown in FIGS. 3G and 3I. After the deposition of the insulating layer 35, its surface may be uneven. Therefore, it can be planarized using the CMP process.

Since we adopt the toggle-mode write-in method, the top write word line of the lower MTJ can be the bottom write word line of the upper MTJ. The planarized insulating layer 35 is further deposited with a fourth insulating layer 40. A common write word line 41 is made in the fourth insulating layer 40. This completes the fabrication of the first-layer memory device, as shown in FIG. 3K.

Afterwards, the memory devices are stacked together. The memory shown in FIG. 3K is deposited with a fifth insulating layer 42. The insulating layers 42, 40, 35 are etched to form the vias, which are then filled with a metal to provide the plugs 43, 44. The plug 43 is in contact with the tape wire 33. The plug 44 is in contact with the connect pad 34, as shown in FIGS. 3K and 3L.

Please refer to FIGS. 4A and 4B for the fabrication of MRAM with a parallel structure. In FIG. 4A, the read word line 24 and the connect pad 25 are formed in the same metal layer. As shown in FIG. 4B, the read word line 24 alone is made on the top layer. It is connected to the lower MTJ using the plug 45. One can produce a serial structure by repeating the above steps, as shown in FIG. 5. To make things easier to understand, we have neglected numeral labels in FIGS. 4 and 5. The structure is similar to those in FIGS. 3A to 3L.

In the parallel structure shown in FIGS. 4A and 4B, the lower electrodes of the upper- and lower-layer memory are connected by the plug 44. The tape read lines are connected using the plug 43, forming the desired parallel structure. In the serial structure of FIG. 5, the plug 44 connects the lower electrodes and the tape read lines of the upper- and lower-layer memory.

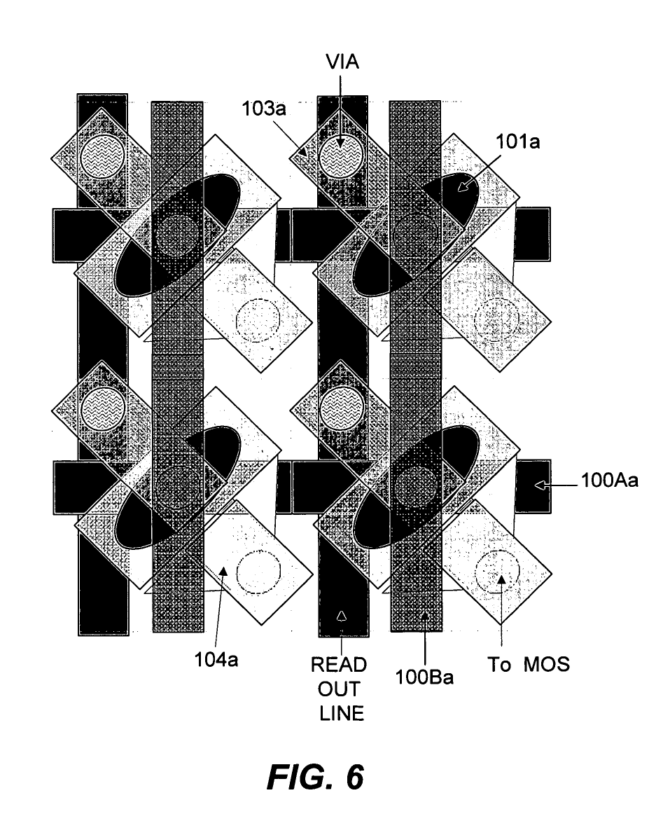

FIG. 6 gives a planar layout. Since we adopt the toggle mode write-in method, the read word line and the write word line are separate and the write word lines are not connected to the MTJ.

We explain in the following paragraphs the circuit layout of the disclosed MRAM with a tape read line.

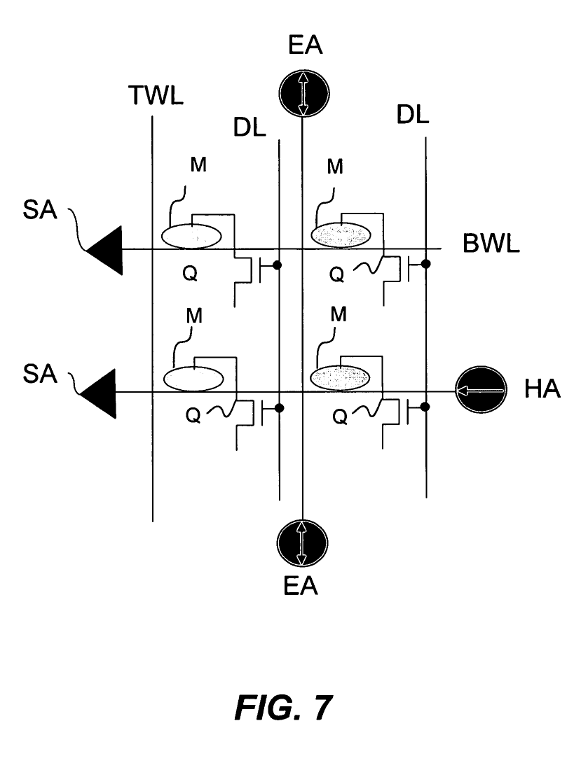

As shown in FIG. 7, the easy axis of the MTJ is parallel to the bottom write word line. The bottom write word line is defined as a word line, and the top write word line is defined as a bit line. As shown in the drawing, the MRAM has an arrayed structure, comprised of several top write word lines TWL and several bottom write word lines BWL, several MRAM's M, several transistors Q, and several data lines DL. The top write word lines TWL are perpendicular to the bottom write word lines BWL. The data lines DL are parallel to the top write word lines TWL and perpendicular to the bottom write word lines BWL. The top write word lines TWL provide a magnetic field required by the easy axis of the MTJ. The MRAM's M and the transistors Q are provided at the intersections of the top write word lines TWL and the bottom write word lines BWL. Each MRAM M is configured with a transistor Q. The gate and drain of the transistor Q are connected to the data line DL and the MRAM M, respectively. The easy axis of the MTJ inside the MRAM M is parallel to the bottom write word line BWL. The data line DL is perpendicular to the bottom write word line BWL so as to read out signals from each of the MRAM's M.

Moreover, the bottom write word line BWL is connected to a sensing amplifier SA to amplify the sensed signals. One end of the top write word line TWL and the bottom write word line BWL is connected to a current source EA, HA, respectively, to provide the necessary current for them to generate a magnetic field. The current source EA is along the easy axis, while the current source HA is along the hard axis.

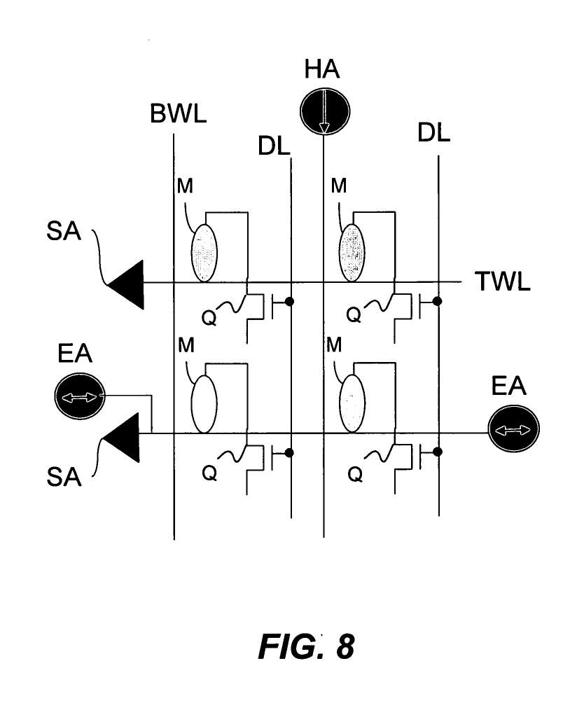

With reference to FIG. 8, the easy axis of the MTJ is parallel to the bottom write word line, defining the bottom write word line as the bit line and the top write word line as the word line. The top write word lines TWL and the bottom write word lines BWL are perpendicular to each other. The data lines DL are perpendicular to the top write word lines TWL, but parallel to the bottom write word lines BWL. The circuit layout is similar to that in FIG. 7. The difference is in that the top write word lines TWL are connected to a sensing amplifier SA to amplify the sensed signals. Each of the top write word lines TWL and the bottom write word lines BWL has one end connected to the current source EA, HA, respectively, to provide the necessary current for them to generate a magnetic field.

The invention discloses a MRAM using the bottom write word lines BWL and the tape read lines TRL to read data. The difference from the conventional structure is in that the MTJ's are directly formed on the bottom write word lines, connected to the data reading transistors via the contacts and the tape read lines. Since there is no via limitation between the top write word lines and the MTJ's, the distance in between can be adjusted according to designs. Besides, the MTJ is in direct contact with the bottom write word line so that a large magnetic field can be produced by the top and bottom write word lines using a smaller write-in current.

In comparison with the prior art, the read-out current for reading memory data according to the disclosed memory directly flows from the bottom write word line to the MTJ, then to the data reading transistor via the tape read line and the contact. The read-out current in the conventional structure flows from the word line to the plug formed on the MTJ, then to the data reading transistor via the lower electrode.

Although the invention has been explained by the embodiments shown in the drawings described above, it should be understood by the person ordinary skilled in the art that the invention is not limited to these embodiments, but rather that various changes or modifications thereof are possible without departing from the spirit and scope of the invention. Accordingly, the scope of the invention shall be determined only by the appended claims and their equivalents.

What is claimed is:

1. A magnetic random access memory (MRAM) with a tape read line, comprising:
a write word line, including a top write word line and a bottom write word line, to provide a channel for a write-in current of the MRAM;
a magnetic tunnel junction (MTJ) formed on the bottom write word line; and
a tape read line formed on the MTJ to provide a channel for a write-out current of the MRAM.

2. The MRAM with a tape read line of claim 1 further comprising a sidewall formed around the MTJ.

3. The MRAM with a tape read line of claim 1 further comprising a contact formed on the top of the MTJ for the tape read line and the MTJ to be in contact with each other.

4. The MRAM with a tape read line of claim 1 further comprising a connect pad connected to the tape read line.

5. The MRAM with a tape read line of claim 4 further comprising a contact formed at the connect pad.

6. The MRAM with a tape read line of claim 1, wherein a lower electrode is formed between the MTJ and the bottom write word line and the lower electrode self aligns the MTJ.

7. A MRAM with a tape read line, comprising:
a plurality of top write word lines and a plurality of bottom write word lines to provide a write-in current channel for the MRAM;
a plurality of MTJ's, each of which is formed on a corresponding bottom write word line by stacking in sequence, wherein the top write word line in the lower MTJ and the bottom write word line in the upper MTJ are shared;
a plurality of tape read lines, each of which is formed on a corresponding MTJ to provide a write-out current channel for the MRAM;
a plurality of lower electrodes, each of which is formed between a corresponding MTJ and a corresponding bottom write word line;
a plurality of first plugs to connect the tape read lines;
a plurality of second plugs to connect the lower electrodes; and
a plurality of third plugs to connect the tape read lines and the lower electrodes.

8. The MRAM with a tape read line of claim 7 further comprising a contact formed on the top of the MTJ for the tape read line and the MTJ to be in contact with each other.

9. The MRAM with a tape read line of claim 7 further comprising a connect pad connected to the tape read line.

10. The MRAM with a tape read line of claim 9 further comprising a contact formed at the connect pad.

11. The MRAM with a tape read line of claim 7, wherein a lower electrode is formed between the MTJ and the bottom write word line and in contact with the bottom of the MTJ.

12. A method for fabricating a MRAM with a tape read line, comprising the steps of:
forming a bottom write word line;
forming a MTJ on the bottom write word line; and
forming a tape read line on the MTJ.

13. The method of claim 12 further comprising the step of forming a contact on the MTJ before the step of forming a tape read line on the MTJ.

14. A method for fabricating a MRAM with a tape read line, comprising the steps of:
forming a MRAM, including the steps of: forming a bottom write word line;
forming a MTJ on the bottom write word line; and forming a tape read line and a connect pad on the MTJ;
forming a top write word line on the MRAM;
forming a first plug connected to the tape read line;
forming a second plug connected to the connect pad; and
forming another MRAM on the top write word line.

15. The method of claim 14 further comprising the step of forming a contact on the MTJ before the step of forming a tape read line on the MTJ.

16. A method for fabricating a MRAM with a tape read line, comprising the steps of:
forming a MRAM, including the steps of: forming a bottom write word line;
forming a MTJ on the bottom write word line; and forming a tape read line and a connect pad on the MTJ;
forming a top write word line on the MRAM;
forming a plug connecting the tape read line and the connect pad; and
forming another MRAM on the top write word line.

17. The method of claim 16 further comprising the step of forming a contact on the MTJ before the step of forming a tape read line on the MTJ.

18. A MRAM circuit, comprising:
a plurality of data lines;
a plurality of top write word lines;
a plurality of bottom write word lines, each of which is perpendicular to each of the top write word lines;
a plurality of MRAM's arranged at the intersections of the plurality of top write word lines and the plurality of bottom write word lines; and
a plurality of transistors provided at the intersections of the plurality of top write word lines and the plurality of bottom write word lines with their gates and drains respectively connected to the data lines and the MRAM's, wherein each of the transistors has a corresponding MRAM.

19. The MRAM circuit of claim 18, wherein the MRAM comprises:
a write word line, including a top write word line and a bottom write word line, to provide a write-in current channel for the MRAM;
a MTJ formed on the bottom write word line and in contact with the write word line;
a sidewall formed around the MTJ; and
a tape read line formed on the MTJ to provide a read-out current channel for the MRAM.

20. The MRAM circuit of claim 18, wherein the data line is parallel to each of the top write word line and perpendicular to each of the bottom write word line.

21. The MRAM circuit of claim 18, wherein the data line is perpendicular to each of the top write word line and parallel to each of the bottom write word line.

22. The MRAM circuit of claim 18, wherein the bottom write word line is connected to a sensing amplifier.

23. The MRAM circuit of claim 18, wherein the top write word line is connected to a sensing amplifier.

24. The MRAM circuit of claim 18, wherein the top write word line and the bottom write word line are connected to a current source, respectively.
